(19) United States
(12) Patent Application Publication
(10) Pub. No.: US 2009/0074127 A1
(43) Pub. Date: Mar. 19, 2009

(54) PHASE LOCKING METHOD AND APPARATUS

(75) Inventor: Rong Liu, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 12/212,791

(22) Filed: Sep. 18, 2008

(30) Foreign Application Priority Data
Sep. 18, 2007 (KR) 2007-94779

(51) Int. Cl. H03D 3/24

(52) U.S. Cl. 375/376; 375/373; 375/327

(57) ABSTRACT

A phase locking method and apparatus by which a phase of an input signal is locked using the input signal and a clock signal, where the phase locking method includes generating n multi-phase clock signals using the clock signal where n is an integer, generating n multi-phase input signals from the input signal corresponding to each of the n multi-phase clock signals, generating n error signals, that is, one for each of the n multi-phase input signals, extracting a low-frequency component from one of the generated n error signals or from a summation result of the generated n error signals, adding the extracted low-frequency component to each of the n error signals, and selecting one of the n error signals to which the low-frequency component is added in response to the clock signal and outputting the selected error signal used to generate the clock signal.

### CROSS-REFERENCE TO RELATED APPLICATION

This application claims the benefit of Korean Application No. 2007-94779, filed Sep. 18, 2007, in the Korean Intellectual Property Office, the disclosure of which is incorporated herein by reference.

### BACKGROUND OF THE INVENTION

1. Field of the Invention

Aspects of the present invention relate to a phase locking method and an apparatus thereof.

2. Description of the Related Art

In order to clearly determine whether an input signal is a logic 0 or 1 signal in transmission of a digital signal using a digital clock signal, a range for distinguishing logic 0 and 1 has to be defined. This refers to the fact that start and end points of each clock signal should be clearly known. However, since signal delays and phase shifts may occur according to a signal path during wired or wireless signal transmission of the digital signal, the start and end points to determine whether an input signal is a logic 0 or 1 signal become unclear at a reception side. Therefore, a method of accurately synchronizing the start and end points of the clock signal is required. Synchronization of the start and end of a signal cycle involves locking a signal as if the signal is received at a particular phase point. In order to lock a periodic signal phase to an accurate fixed point, a circuit known as a phase locked loop (PLL) is used. Since a phase is conceptually an integral of frequency, phase locking and frequency locking are conceptually similar to each other.

The PLL is a type of negative feedback circuit in which a signal is continuously cycled until the signal has a same frequency as a reference frequency so as to make a frequency of an input signal the same as the reference frequency, make a frequency of an output signal the same as the reference frequency, or convert an internal clock signal frequency into an integral multiple of an external clock signal frequency. The PLL detects a phase difference of the input signal based on the output signal and controls a voltage controlled oscillator (VCO) or a digital controlled oscillator (DCO) using the detected phase difference, to thereby output a fixed-frequency signal. Hereinafter, a typical PLL will be described with reference to FIGS. 1 through 3. The technical features illustrated in FIGS. 1 through 3 are disclosed in Japanese Laid-open Patent Application No. 2006-338726.

FIG. 1 is a block diagram of a phase locking unit 30. Referring to FIG. 1, the phase locking unit 30 includes an analog-to-digital converter (A/D) 11, an oscillator 12, a serial-to-parallel converter 21, an interpolator 23, a partial response (PR) equalizer 24, a phase detector 25, a low pass filter (LPF) 26, a timing controller 27 and a modular selector 31. The analog-to-digital converter (A/D) 11 samples an analog input signal Si according to a predetermined-frequency clock signal provided by the oscillator 12 in order to generate a digital input data signal Ds, and provides the generated digital input data signal Ds to the serial-to-parallel converter 21.

The serial-to-parallel converter 21 converts the digital input data signal Ds to a 4-channel parallel input data signal and provides the 4-channel parallel input data signal to the interpolator 23. The interpolator 23 interpolates the 4-channel parallel input data signal according to 4 types of sampling phase signals μ0 through μ3 provided from the timing controller 27 in order to generate interpolated data signals Di0 through Di3, and provides the generated interpolated data signals Di0 through Di3 to the modular selector 31.

The modular selector 31 transforms the interpolated data signals Di0 through Di3 according to 4 types of enable signals en0 through en3 provided from the timing controller 27 and outputs the transformed interpolated data signals Di0 through Di3 to the PR equalizer 24. The PR equalizer 24 performs predetermined PR equalization on the transformed interpolated data signals Di0 through Di3 provided from the modular selector 31, in order to generate PR-equalized data signals y0 through y3, and outputs the PR-equalized data signals y0 through y3 to the phase detector 25. The phase detector 25 receives the PR-equalized data signals y0 through y3 and provides phase errors ΔT0 through ΔT3 to the low pass filter (LPF) 26.

The low pass filter (LPF) 26 extracts low-frequency components from the phase errors ΔT0 through ΔT3 provided from the phase detector 25, in order to generate sampling phase differences Δμ0 through Δμ3, and provides the generated sampling phase differences Δμ0 through Δμ3 to the timing controller 27. The timing controller 27 generates timing information, i.e., the sampling phase signals μ0 through μ3, based on the sampling phase differences Δμ0 through Δμ3 provided from the LPF 26 and provides the generated timing information to the interpolator 23. The timing controller 27 also generates the enable signals en0 through en3 based on the sampling phase differences Δμ0 through Δμ3 and provides the generated enable signals en0 through en3 to the interpolator 23 and the modular selector 31.

FIG. 2 illustrates in detail the phase detector 25 of the phase locking unit 30 illustrated in FIG. 1. Referring to FIG. 2, the phase detector 25 provides the PR-equalized data signals y0 through y3 provided from the PR equalizer 24 to multipliers 130 through 133. The phase detector 25 also provides the PR-equalized data signals y0 through y2 to multipliers 135 through 137, delays the remaining PR-equalized data signal y3 by 1 time slot using a first delay circuit 138 in order to generate a data signal y3D, and then provides the generated data signal y3D to a multiplier 134. The phase detector 25 detects whether each of the PR-equalized data signals y0 through y3 is a zero-cross signal using a zero-cross detection circuit (not shown), provides detection result signals a0 through a3 to the multipliers 134 through 137 and the detection result signals a0 through a2 to the multipliers 131 through 133, delays the detection result a3 by 1 time slot using a second delay circuit 139 in order to generate a data signal a3D, and provides the generated data signal a3D to a multiplier 130.

The multipliers 130 through 133 multiply the PR-equalized data signals y0 through y3 by the detection result signals a3D, a2, a1 and a0, respectively, in order to generate multiplication result signals y0*a3D, y1*a0, y2*a1, and y3*a2, and provides the generated multiplication result signals y0*a3D, y1*a0, y2*a1, and y3*a2 to corresponding subtractors 140 through 143. The multipliers 134 through 137 multiply the PR-equalized data signals y3d, y2, y1, and y0 by the detection result signals a0, al, a2, and a3, respectively, in order to generate multiplication result signals y3D*a0, y0*a1, y1*a2, and y2*a3, and provides the generated multiplication result signals y3D*a0, y0*a1, y1*a2, and y2*a3 to corresponding subtractors 140 through 143. The subtractors 140 through 143 subtracts y0*a3D from y3D*a0 in order to generate the phase error ΔT0, subtracts y1*a0 from y0*a1 in order to generate the phase error ΔT1, subtracts y2*a1 from y1*a2 in order to generate the phase error ΔT2, and subtracts y3*a2 from y2*a3 in order to generate the phase error ΔT3.

FIG. 3 illustrates in detail the LPF 26 of the phase locking unit 30 illustrated in FIG. 1. Referring to FIG. 3, the phase errors ΔT0 through ΔT3 from the phase detector 25 are provided to multipliers 150 through 153. The multipliers 150 through 153 multiply the phase errors ΔT0 through ΔT3 by a coefficient a. Delay circuits 154 through 157 delay the multiplication results by 1 time slot and provide the delay results to adders 158 through 161. The LPF 26 provides the phase error ΔT0 to adders 162 and 163 and provides the phase error ΔT1 to the adder 163. The adder 163 provides the result of ΔT0+ΔT1 to adders 164 and 165. The LPF 26 provides the phase error ΔT2 to adders 165 and 167 and the adders 165 and 167 provides the result of ΔT0+ΔT1+ΔT2 to an adder 168. The LPF 26 provides the phase error ΔT3 to the adder 167 and the adder 167 provides the result of ΔT2+ΔT3 to an adder 166. The adder 166 provides the result Of ΔT0+ΔT1+ΔT2+ΔT3 to an adder 169.

A delay circuit 170 delays the addition result provided from the adder 169 by 1 time slot and provides the delay result to the adders 162, 164, 168, and 169. The timing controller 27 calculates timing differences v0 through v3 and provides the calculated timing differences v0 through v3 to delay circuits 179 through 182. The LPF 26 subtracts the delay results with respect to the timing differences v0 through v3 using subtractors 183 through 186. Multipliers 187 through 190 multiply the subtraction results from the subtractors 183 through 186 by an over-sampling rate ε. Delay circuits 191 through 194 delay the multiplication results by 1 time slot in order to generate the sampling phase differences Δμ0 through Δμ3.

The phase locking unit 30 described above and disclosed in Japanese Laid-open Patent Application No. 2006-338726 performs phase locking by processing a serial signal into a parallel signal, thereby improving its processing speed as compared to serial processing. However, the LPF 26 extracts low-frequency components of the phase errors ΔT0 through ΔT3 using all the phase errors ΔT0 through ΔT3, thereby consuming a large amount of time, and thus, causing loop delay and bad tracking.

### SUMMARY OF THE INVENTION

Aspects of the present invention provide a phase locking method and an apparatus thereof by which a critical path processing speed can be increased.

Aspects of the present invention also provide a phase locking method and an apparatus thereof by which a time delay caused by a loop delay can be reduced.

Aspects of the present invention also provide a phase locking method and an apparatus thereof by which the number of logic gates required is reduced by simplifying an integration block.

According to one aspect of the present invention, a phase locking method by which the phase of an input signal is locked using the input signal and a clock signal, includes generating n multi-phase clock signals using the clock signal where n is an integer, generating n multi-phase input signals from the input signal corresponding to each of the generated n multi-phase clock signals, generating n error signals, one for each of the generated n multi-phase input signals, extracting a low-frequency component from one of the generated n error signals or from a summation result of the generated n error signals, adding the extracted low-frequency component to each of the generated n error signals, and selecting one of the n error signals to which the low-frequency component is added in response to the clock signal and outputting the selected error signal used to generate the clock signal.

According to an aspect of the present invention, the generation of the n multi-phase clock signals may include generating n multi-phase clock signals each having a same cycle and a phase difference that is an integral multiple of 1/n of the cycle. The generation of the n error signals may include obtaining a zero-cross point for each of the generated n multi-phase input signals and sampling each of the generated n multi-phase input signals at the obtained zero-cross point in response to the multi-phase clock signal corresponding to the multi-phase input signal, in which a value of each of the generated n multi-phase input signals sampled at the zero-cross point corresponds to each of the generated n error signals. The extraction of the low-frequency component from the selected error signal may include selecting an error signal which is sampled at the temporally latest zero cross point, from among the generated n error signals. The extraction of the low-frequency component from the selected error signal may further include amplifying the selected error signal and extracting the low-frequency component from the selected error signal by integrating the amplified error signal. The addition of the extracted low-frequency component to each of the n error signals may include amplifying each of the n error signals and adding the extracted low-frequency component to each of the amplified n error signals. The phase locking method may further include generating a control signal by selecting one of the generated n error signals to which the extracted low-frequency component is added in response to the clock signal and outputting the selected error signal and generating a new clock signal using the generated control signal. The phase locking method may further include generating an input signal in a digital form by sampling the input signal in an analog form using a fixed asynchronous clock signal, in which the generation of the n multi-phase input signals from the input signal comprises generating the n multi-phase input signals from the input signal in the digital form corresponding to each of the n multi-phase clock signals.

According to another aspect of the present invention, a phase locking apparatus in which a phase of an input signal is locked using the input signal and a first clock signal, includes a multi-phase clock signal generation unit to generate n multi-phase clock signals using the first clock signal, an analog-to-digital converter (ADC) to generate n multi-phase input signals from the input signal corresponding to each of the generated n multi-phase clock signals, a phase detection unit to generate n error signals, one for each of the generated n multi-phase input signals, a control signal generation unit to extract a low-frequency component from one of the generated n error signals or from a summation result of the generated n error signals, to add the extracted low-frequency component to each of the generated n error signals, and to generate a control signal by selecting one of the generated n error signals to which the low-frequency component is added in response to the first clock signal and to output the selected error signal used to generate a second clock signal, and a voltage controlled oscillator (VCO) to generate the second clock signal according to the control signal.

According to another aspect of the present invention, a phase locking method of locking a phase of an input signal using a clock signal, includes: generating a plurality of digital multiphase input signals from an analog input signal using respective ones of a plurality of multiphase clock signals; generating a plurality of error signals from the corresponding plurality of digital multiphase input signal based on a phase delay between the plurality of digital multiphase input signals and corresponding ones of the plurality of multiphase clock signals; obtaining a low frequency component of only one of the error signals; amplifying the plurality of error signals and adding the low frequency component to each of the plurality of amplified error signals to generate respective modified error signals; and generating a new clock signal used to generate the plurality of multiphase clock signals from only one of the modified error signals.

According to another aspect of the present invention, a phase locking apparatus to lock a phase of an input signal using a clock signal, includes: an analog to digital converter to generate a plurality of digital multiphase input signals from an analog input signal using respective ones of a plurality of multiphase clock signals; a phase detector to generate a plurality of error signals from the corresponding plurality of digital multiphase input signal based on a phase delay between the plurality of digital multiphase input signals and corresponding ones of the plurality of multiphase clock signals; and a control signal generator to obtain a low frequency component of only one of the error signals, to amplify the plurality of error signals and add the low frequency component to each of the plurality of amplified error signals to generate respective modified error signals, and to generate a new clock signal used to generate the plurality of multiphase clock signals from only one of the modified error signals.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the aspects, taken in conjunction with the accompanying drawings of which:

FIG. 1 is a block diagram of a typical phase locking unit;

FIG. 2 illustrates in detail a phase detector of the typical phase locking unit illustrated in FIG. 1;

FIG. 3 illustrates in detail a low pass filter (LPF) of the typical phase locking unit illustrated in FIG. 1;

FIG. 4 is a block diagram of a phase locking apparatus according to an aspect of the present invention;

FIG. 5 illustrates in detail the phase locking apparatus illustrated in FIG. 4, according to an aspect of the present invention;

FIGS. 6A-6F illustrate multi-phase clock signals generated by a multi-phase clock signal generation unit illustrated in FIG. 5, according to an aspect of the present invention;

FIG. 7 illustrates in detail an error signal selection unit according to an aspect of the present invention; and

FIG. 8 is a flowchart illustrating a phase locking method according to an aspect of the present invention.

### DETAILED DESCRIPTION OF THE EMBODIMENTS

Reference will now be made in detail to aspects of the present invention, examples of which are illustrated in the accompanying drawings, wherein like reference numerals refer to the like elements throughout. The aspects are described below in order to explain the present invention by referring to the figures.

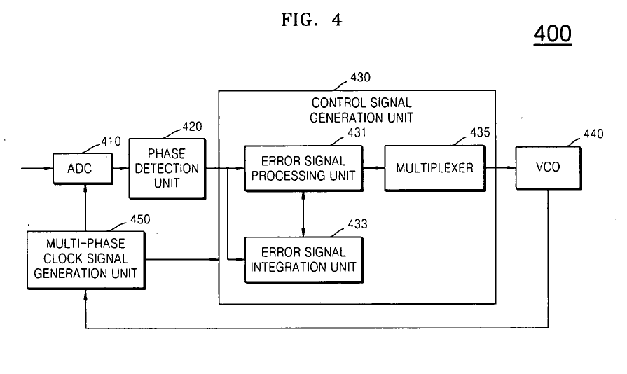

FIG. 4 is a block diagram of a phase locking apparatus according to an aspect of the present invention. Referring to FIG. 4, the phase locking apparatus 400 includes an analog-to-digital converter (ADC) 410, a phase detection unit 420, a control signal generation unit 430, a voltage controlled oscillator (VCO) 440, and a multi-phase clock signal generation unit 450.

The ADC 410 samples and quantizes an analog input signal in order to generate a digital input signal. In this aspect, the ADC 410 converts the analog input signal in a serial signal form into n parallel digital signals (digital multi-phase input signals) based on multi-phase clock signals provided from the multi-phase clock signal generation unit 450, where n is a natural number. The ADC 410 may also generate the digital input signal by sampling the analog input signal with a fixed asynchronous clock signal without using the multi-phase clock signals provided from the multi-phase clock signal generation unit 450. In an aspect of the present invention, in order to generate the n digital multi-phase input signals from the digital input signal to correspond to the n multi-phase clock signals, an interpolator (not shown) may be used between the ADC 410 and the phase detection unit 420.

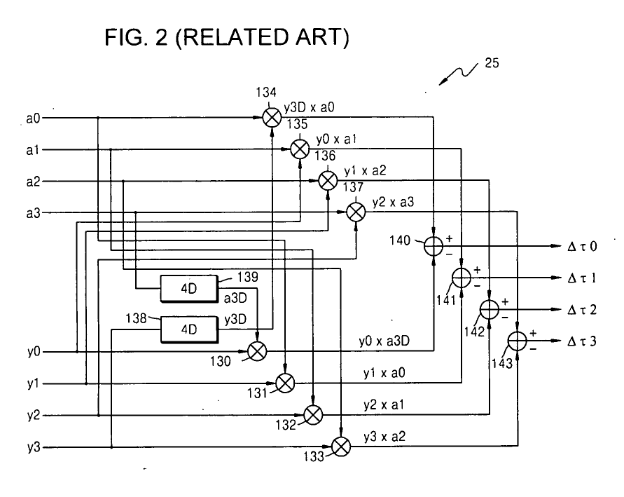

The ADC 410 outputs the digital multi-phase input signals in a parallel signal form to the phase detection unit 420. The phase detection unit 420 detects an error signal for each of the digital multi-phase input signals provided from the ADC 410. A method of error signal detection useable by the phase detection unit 420 has already been described with reference to FIG. 2, and thus, a description of the method will not be repeated. The phase detection unit 420 outputs detected n error signals to the control signal generation unit 430.

The control signal generation unit 430 generates a control signal for driving the VCO 440 using the n error signals. To this end, the control signal generation unit 430 includes an error signal processing unit 431, an error signal integration unit 433, and a multiplexer 435. The signal integration unit 433 selects one of the n error signals output from the phase detection unit 420. The error signal integration unit 433 integrates the selected error signal in order to extract a low-frequency component thereof, and outputs the extracted low-frequency component to the error signal processing unit 431.

The error signal processing unit 431 amplifies each of the n error signals and adds the extracted low-frequency component output from the error signal integration unit 433 to each of the n amplified error signals. The error signal processing unit 431 temporarily stores the n amplified error signals to which the low-frequency component have been added in corresponding buffers (not shown). The multiplexer 435 selects one of the n amplified error signals stored in the buffers in response to a clock signal and outputs the selected amplified error signal. The VCO 440 generates a new clock signal using the selected amplified error signal output from the multiplexer 435. The VCO 440 may be a digitally controlled oscillator (DCO) or a numeric controlled oscillator (NCO).

The multi-phase clock signal generation unit 450 generates a plurality of multi-phase clock signals using the clock signal generated by the VCO 440 and outputs the generated plurality of multi-phase clock signals to the ADC 410 and the control signal generation unit 430.

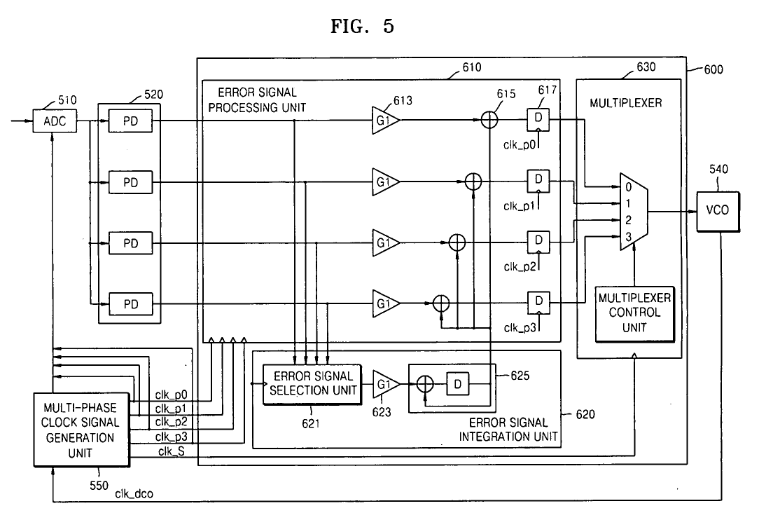

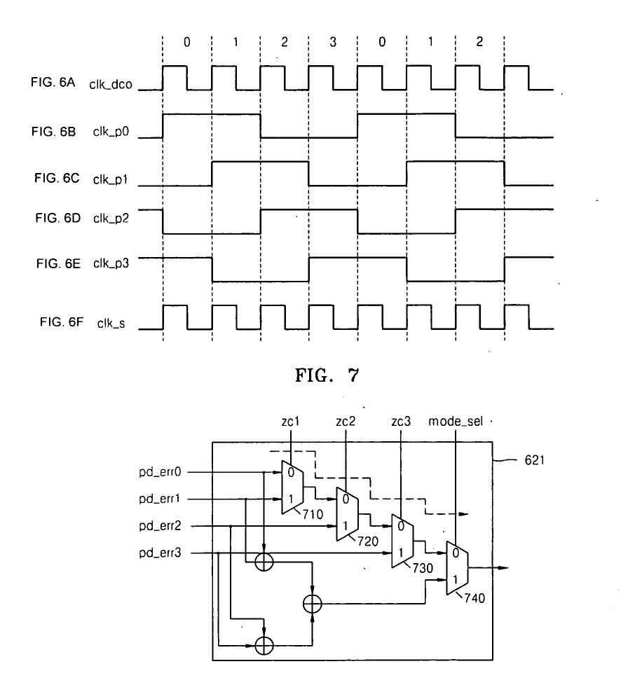

FIG. 5 illustrates in detail an example of the phase locking apparatus 400 illustrated in FIG. 4, and FIGS. 6A-6F illustrate multi-phase clock signals generated by the multi-phase clock signal generation unit 550 illustrated in FIG. 5, according to an aspect of the present invention. Referring to FIG. 5, the phase locking apparatus 400 includes an ADC 510, a phase detection unit 520, a control signal generation unit 600, a VCO 540, and a multi-phase clock signal generation unit 550. The control signal generation unit 600 includes an error signal processing unit 610, an error signal integration unit 620, and a multiplexer 630.

The VCO 540 generates a clock signal clk_dc0 and outputs the generated clock signal clk_dc0 to the multi-phase clock signal generation unit 550. The multi-phase clock signal generation unit 550 generates a plurality of multi-phase clock signals clk_p0 through clk_pn-1 using the clock signal clk_dc0 generated by the VCO 540. The multi-phase clock signal generation unit 550 divides the clock signal clk_dc0 generated by the VCO 540 using a divider (not shown) in order to generate n multi-phase clock signals (for example, clk_p0 through clk_μ3 when n is 4), each of which has a cycle that is n times that of the clock signal, and has a phase difference amount that is 1/n the cycle (which is n times that of the clock signal clk_dc0), in which n is an integer. For example, it is assumed that the VCO 540 generates the clock signal clk_dc0 illustrated in FIG. 6A.

In an aspect of the present invention where n is 4, the multi-phase clock signal generation unit 550 generates multi-phase clock signals clk_p0 through clk_p3 using the clock signal clk_dc0. In FIGS. 6B to 6E, each of the multi-phase clock signals clk μ0 through clk_p3 has a cycle that is 4 times that of the clock signal clk_dc0 and a phase that is delayed by a ¼ of the cycle (which is n times that of the clock signal clk_dc0). The multi-phase clock signal generation unit 550 outputs the multi-phase clock signals clk
through clk_p3 to the ADC 510, and the clk_p0 through clk_p3 and a clock signal clk_s having the same cycle and phase as those of the clock signal clk_dc0 to the control signal generation unit 600.

The ADC 510 samples an analog input signal according to the multi-phase clock signals clk_p0 through clk_p3 in order to generate digital multi-phase input signals. In FIG. 5, the ADC 510 generates 4 digital multi-phase input signals in a parallel signal form according to 4 multi-phase clock signals clk_p0 through clk_p3 and outputs the 4 digital multi-phase input signals to corresponding 4 phase detectors (PDs) included in the phase detection unit 520. The PDs included in the phase detector 520 detect respective error signals from the respective digital multi-phase input signals corresponding to the multi-phase clock signals clk_p0 through clk_p3. To this end, the phase detection unit 520 obtains a zero-cross point of each of the digital multi-phase input signals. In aspects of the present invention, a zero-cross point refers to a point where a sign change of a signal occurs. In an aspect of the present invention, the zero-cross point would be a point where a voltage value of the signal having a wave form is zero.

Each of the PDs samples each digital multi-phase input signal at each zero-cross point in response to the corresponding multi-phase clock signal clk_p0 through clk_p3. When the phase of the digital multi-phase input signal is the same as that of the corresponding multi-phase clock signal clk_p0 through clk_p3, the digital multi-phase input signal sampled at the zero-cross point has a value of 0. In other words, when the value of the digital multi-phase input signal sampled at the zero-cross point is not 0, the digital multi-phase input signal and the corresponding multi-phase clock signal clk_p0 through clk_p3 do not have the same phase. The phase detection unit 520 outputs as error signals, values of the multi-phase input signals sampled at the zero-cross point to the error signal processing unit 610 and the error signal integration unit 620 included in the control signal generation unit 600. In this aspect of the present invention, the phase detection unit 520 outputs 4 error signals. In other aspects, a number other than 4 is possible, according to a variation of n multi-phase clock signals.

The error signal integration unit 620 includes an error signal selection unit 621, an amplification unit 623, and an integration unit 625. The error signal integration unit 620 may be operated by one of the multi-phase clock signals clk_p0 through clk_p3. For example, the error signal integration unit 620 may be operated by the multi-phase clock signal clk_p3 whose phase is delayed by the largest amount, as shown in FIG. 6E. The error signal selection unit 621 selects one of 4 error signals detected by the phase detection unit 520. According to an aspect of the present invention, by performing integration processing using only one error signal from among a plurality of error signals, time consumed by integrating the error signals can be reduced. The amplification unit 623 amplifies the selected error signal and outputs the amplified selected error signal to the integration unit 625. The integration unit 625 integrates the amplified selected error signal in order to extract a low-frequency component thereof.

The error signal processing unit 610 includes an amplification unit 613, an addition unit 615, and a buffering unit 617. The error signal processing unit 610 amplifies each of the 4 error signals output from the phase detection unit 520 using the amplification unit 613. The error signal processing unit 610 adds the extracted low-frequency component from the integration unit 625 to each of the 4 amplified error signals using the addition unit 615, and temporarily stores the respective error signals to which the low-frequency component is added in the buffering unit 617. The multiplexer 630 outputs one of the error signals stored in the buffering unit 617 in response to a clock signal, such as the clk_s. The one error signal output from the multiplexer 630 controls the VCO 540 in order to generate a new clock signal clk_dc0.

FIG. 7 illustrates in detail an example of the error signal selection unit 621 according to an aspect of the present invention. Referring to FIG. 7, the error signal selection unit 621 includes first through fourth error signal processing multiplexers 710 through 740. The first through fourth error signal processing multiplexers 710 through 740 receive a plurality of error signals pd_err0 through pd_err3 and select one of the error signals pd_err0 through pd_err3. A criterion for error signal selection may vary, and may be input using corresponding selection signals zc1, zc2, and zc3 according to a mode select signal mode_set. In other words, the first through fourth error signal processing multiplexers 710 through 740 may select one of the error signals pd_err0 through pd_err3 at random or select one of the error signals pd_err0 through pd_err3 detected at a relatively more later zero-cross point. The first through fourth error signal processing multiplexers 710 through 740 may also select one of the error signals pd_err0 through pd_err3 that corresponds to a multi-phase input signal that is synchronized to a multi-phase clock signal with a largest amount of phase-delay among the multi-phase input signals clk_p0 through clk_p3.

In the aspect shown in FIG. 7, the first error signal processing multiplexer 710 receives two of the error signals pd_err0 and pd_err1, selects one of the error signals pd_err0 and pd_err1 using one of the above discussed criteria for error signal selection, and outputs the selected error signal. When the first error signal processing multiplexer 710 makes a selection based on a phase, the first error signal processing multiplexer 710 may select the error signal pd_err1 generated from a multi-phase input signal that is synchronized to a multi-phase clock signal having a largest amount of phase delay. The second error signal processing multiplexer 720 may likewise select the error signal pd_err2 between the input error signal pd_err2 and the error signal pd_err1 selected by the first error signal processing multiplexer 710 based on the largest amount of phase delay. Likewise, the third error signal processing multiplexer 730 may select an input error signal pdd_err3 between the input error signal pdd_err3 and the error signal pd_err2 selected by the second error signal processing multiplexer 720 based on phase delay. It should be understood that in other aspects of the present invention, the first through fourth error signal processing multiplexers 710-740 may respectively select one of first through fourth error signals pd_err0 through pd_err3 using other criteria for error signal selection, such as simply choosing one randomly.

In an aspect of the present invention, the error signal selection unit 621 may perform one of, a method of selecting one of a plurality of error signals and integrating the selected error signal, and a method of summing the error signals and integrating the summation result. In FIG. 7, the fourth error signal processing multiplexer 740 may output an error signal selected from among a plurality of error signals or output the summation result of the error signals according to a user selected method. In other words, it is an option whether to use a summation unit.

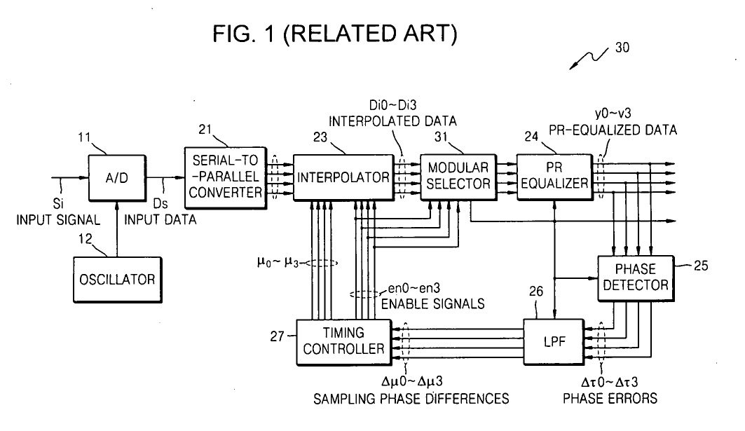

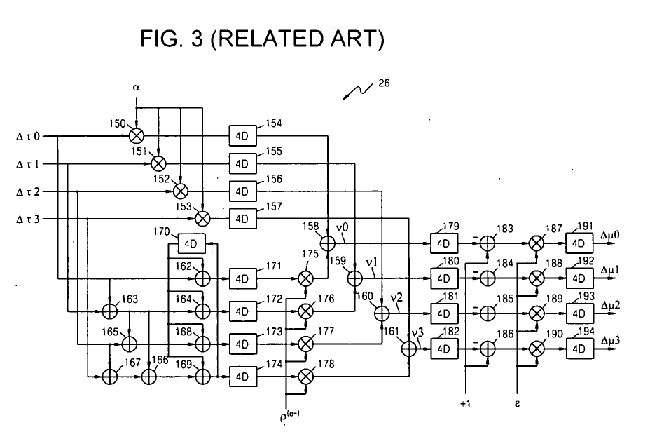

According to the typical technique discussed above in reference to FIGS. 1-3, the LPF 26 extracts a low-frequency component of a phase error signal using a summation result of a plurality of the phase error signals, causing a signification amount of delay in the summation process. In other words, in FIG. 3, the adder 166 has to sequentially add phase errors of signals in order to provide the result ΔT0+ΔT1+ΔT2+ΔT3 to the adder 169, thereby consuming a large amount of time. However, according to an aspect of the present invention, one error signal among a plurality of error signals is selected without addition of respective phase errors and thus, the error signal selection unit 621 can substitute for adders. For example, the error signal pd_err3 input to the third error signal processing multiplexer 730 can be directed to the integration unit 625 without being delayed as a result of external processing. In other words, time delay caused by error signal processing can be reduced.

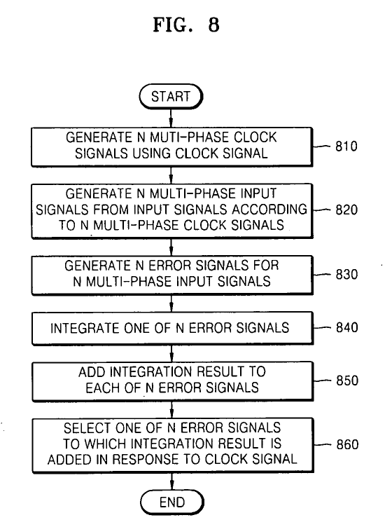

FIG. 8 is a flowchart illustrating a phase locking method using the phase locking apparatus illustrated in FIG. 4, according to an aspect of the present invention. Referring to FIG. 8, the multi-phase clock signal generation units 450 and 550 generate n multi-phase clock signals using a clock signal (in operation 810). In an aspect of the present invention, the multi-phase clock signal generation units 450 and 550 may generate n multi-phase clock signals each having a same cycle and a phase difference of an integral multiple of 1/n of the cycle. The ADCs 410 and 510 generate n digital multi-phase input signals from an analog input signal according to the n multi-phase clock signals (in operation 820) and output each of the n digital multi-phase input signals to the respective phase detection units 420 and 520. The phase detection unit 420 and 520 generate n error signals, one for each of the n digital multi-phase input signals (in operation 830). To this end, the phase detection units 420 and 520 obtain a zero-cross point for each of the n digital multi-phase input signals and sample the n digital multi-phase input signals at the zero-cross points in response to the multi-phase clock signals corresponding to the n digital multi-phase input signals.

The error signal integration units 433 and 620 select one of the n error signals and integrate the selected error signal (in operation 840). As described previously, the method of selecting the error signal may vary. In an aspect of the present invention, the error signal integration units 433 and 620 may select an error signal sampled at a temporally later or latest zero-cross point from among the n error signals. The error signal integration units 433 and 620 amplify the selected error signal and integrate the amplified error signal in order to extract a low-frequency component from the selected error signal. The error signal processing units 431 and 610 amplify each of the n error signals and add the integration result to the amplification result (in operation 850). The multiplexers 435 and 630 select one of the n error signals to which the integration result is added and output the selected error signal in response to the clock signal (in operation 860). The VCOs 440 and 540 generate a new clock signal using the error signal output from the multiplexers 435 and 630 and repeat phase locking.

According to aspects of the present invention, a critical path processing speed can be improved. Moreover, expended time caused by a loop delay can be reduced. Furthermore, a number of logic gates required can be reduced by simplifying an integration block.

In FIGS. 4 and 5, although various elements such as the phase detection unit 520, the amplification unit 613, the addition unit 615, and the buffering unit 617, for example, are shown as having 4 separate sub elements, the numbers thereof need not be 4, and may correspond to integer n in other aspects.

Aspects of the present invention can also be embodied as a program that can be implemented on a computer and a general-purpose digital computer executing the program using a computer-readable recording medium. Examples of the computer readable recording medium include magnetic recording media such as read-only memory (ROM), random-access memory (RAM), floppy disks, and hard disks, optical data storage devices such as CD-ROMs and digital versatile disks (DVDs). Aspects can be implemented as carrier waves, such as transmission over the Internet.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A phase locking method by which the phase of an input signal is locked using the input signal and a clock signal, the phase locking method comprising:
generating n multi-phase clock signals using the clock signal, where n is an integer;
generating n multi-phase input signals from the input signal corresponding to each of the generated n multi-phase clock signals;
generating n error signals, one for each of the generated n multi-phase input signals;
extracting a low-frequency component from one of the generated n error signals or from a summation result of the generated n error signals;
adding the extracted low-frequency component to each of the generated n error signals; and
selecting one of the n error signals to which the low-frequency component is added in response to the clock signal and outputting the selected error signal to generate the clock signal.

2. The phase locking method of claim 1, wherein the generation of the n multi-phase clock signals comprises generating n multi-phase clock signals each having a same cycle and a phase difference that is an integral multiple of 1/n of the cycle.

3. The phase locking method of claim 1, wherein the generation of the n error signals comprises:
obtaining a zero-cross point for each of the generated n multi-phase input signals; and
sampling each of the generated n multi-phase input signals at the obtained zero-cross point in response to the multi-phase clock signal corresponding to the multi-phase input signal,
wherein a value of each of the generated n multi-phase input signals sampled at the zero-cross point corresponds to each of the n error signals.

4. The phase locking method of claim 3, wherein the extraction of the low-frequency component from the selected error signal comprises selecting an error signal which is sampled at a temporally latest zero cross point, from among the generated n error signals.

5. The phase locking method of claim 4, wherein the extraction of the low-frequency component from the selected error signal further comprises:
amplifying the selected error signal; and
extracting the low-frequency component from the selected error signal by integrating the amplified error signal.

6. The phase locking method of claim 5, wherein the addition of the extracted low-frequency component to each of the generated n error signals comprises:
amplifying each of the generated n error signals; and
adding the extracted low-frequency component to each of the amplified n error signals.

7. The phase locking method of claim 1, further comprising:
generating a control signal by selecting one of the generated n error signals to which the extracted low-frequency component is added in response to the clock signal and outputting the selected error signal; and
generating a new clock signal using the generated control signal.

8. The phase locking method of claim 1, further comprising generating an input signal in a digital form by sampling the input signal in an analog form using a fixed asynchronous clock signal,
wherein the generation of the n multi-phase input signals from the input signal comprises generating the n multi-phase input signals from the input signal in the digital form corresponding to each of the generated n multi-phase clock signals.

9. A phase locking apparatus in which a phase of an input signal is locked using the input signal and a first clock signal, the phase locking apparatus comprising:
a multi-phase clock signal generation unit to generate n multi-phase clock signals using the first clock signal, where n is an integer;
an analog-to-digital converter (ADC) to generate n multi-phase input signals from the input signal corresponding to each of the generated n multi-phase clock signals;
a phase detection unit to generate n error signals, one for each of the n multi-phase input signals;
a control signal generation unit to extract a low-frequency component from one of the generated n error signals or from a summation result of the generated n error signals, to add the extracted low-frequency component to each of the generated n error signals, and to generate a control signal by selecting one of the generated n error signals to which the low-frequency component is added in response to the first clock signal and to output the selected error signal used to generate a second clock signal; and
a voltage controlled oscillator (VCO) to generate the second clock signal according to the control signal.

10. The phase locking apparatus of claim 9, wherein the control signal generation unit comprises:
an error signal integrating unit to select one of the generated n error signals and to extract the low-frequency component from the selected error signal;
an error signal processing unit to amplify each of the generated n error signals and to add the extracted low-frequency component to each of the amplified n error signals; and
a multiplexer to generate the control signal by selecting one of the generated n error signals to which the low-frequency component is added in response to the first clock signal and to output the selected error signal.

11. The phase locking apparatus of claim 10, wherein each of the generated n multi-phase clock signals has a same cycle and a phase difference that is an integral multiple of 1/n of the cycle.

12. The phase locking apparatus of claim 10, wherein the phase detection unit obtains a zero-cross point for each of the generated n multi-phase input signals and samples each of the generated multi-phase input signals at the obtained zero-cross point in response to the multi-phase clock signal corresponding to the generated multi-phase input signal, such that a value of each of the generated multi-phase input signals sampled at the zero-cross point corresponds to each of the generated n error signals.

13. The phase locking apparatus of claim 12, wherein the error signal integration unit selects an error signal which is sampled at a temporally latest zero-cross point, from among the generated n error signals.

14. The phase locking apparatus of claim 13, wherein the error signal integration unit amplifies the selected error signal, integrates the amplified error signal, and extracts the low-frequency component from the selected error signal.

15. The phase locking apparatus of claim 14, wherein the error signal processing unit amplifies each of the generated n error signals and adds the extracted low-frequency component to each of the amplified n error signals.

16. The phase locking apparatus of claim 9, wherein the ADC generates an input signal in a digital form by sampling the input signal in an analog form using a fixed asynchronous clock signal and the phase locking apparatus further comprises an interpolator to generate the n multi-phase input signals from the input signal in the digital form corresponding to each of the generated n multi-phase clock signals.

17. A phase locking method of locking a phase of an input signal using a clock signal, the method comprising:
generating a plurality of digital multiphase input signals from an analog input signal using respective ones of a plurality of multiphase clock signals;
generating a plurality of error signals from the corresponding plurality of digital multiphase input signal based on a phase delay between the plurality of digital multiphase input signals and corresponding ones of the plurality of multiphase clock signals;
obtaining a low frequency component of only one of the error signals;
amplifying the plurality of error signals and adding the low frequency component to each of the plurality of amplified error signals to generate respective modified error signals; and
generating a new clock signal used to generate the plurality of multiphase clock signals from only one of the modified error signals.

18. The phase locking method of claim 17, wherein the only one of the error signals whose low frequency component is obtained is one that corresponds to one of the plurality of digital multiphase input signals that is synchronized to one of the plurality of multiphase clock signals with a largest amount of phase delay among the digital multi-phase input signals.

19. A phase locking apparatus to lock a phase of an input signal using a clock signal, the apparatus comprising:
an analog to digital converter to generate a plurality of digital multiphase input signals from an analog input signal using respective ones of a plurality of multiphase clock signals;
a phase detector to generate a plurality of error signals from the corresponding plurality of digital multiphase input signal based on a phase delay between the plurality of digital multiphase input signals and corresponding ones of the plurality of multiphase clock signals; and
a control signal generator to obtain a low frequency component of only one of the error signals, to amplify the plurality of error signals and add the low frequency component to each of the plurality of amplified error signals to generate respective modified error signals, and to generate a new clock signal used to generate the plurality of multiphase clock signals from only one of the modified error signals.

20. The phase locking apparatus of claim 19, wherein the only one of the error signals whose low frequency component is obtained is one that corresponds to one of the plurality of digital multiphase input signals that is synchronized to one of the plurality of multiphase clock signals with a largest amount of phase delay among the digital multi-phase input signals.
